(19) United States
(12) Patent Application Publication
(10) Pub. No.: US 2026/0078961 A1
(43) Pub. Date: Mar. 19, 2026

(54) COOLING COMPONENT

(71) Applicant: ERWIN QUARDER SYSTEMTECHNIK GMBH, Espelkamp (DE)

(72) Inventors: Georg SIEWERT, Pohlheim (DE); Stefan BRUNS, Osnabrück (DE); Alexander HEITBRINK, Stemwede (DE)

(73) Assignee: ERWIN QUARDER SYSTEMTECHNIK GMBH, Espelkamp (DE)

(21) Appl. No.: 19/396,835

(22) Filed: Nov. 21, 2025

Related U.S. Application Data
(63) Continuation of application No. PCT/EP2024/064166, filed on May 23, 2024.

(30) Foreign Application Priority Data
May 24, 2023 (DE) 102023113544.9

(51) Int. Cl. F28D 9/00

(52) U.S. Cl. CPC F28D 9/0075

(57) ABSTRACT

A cooling component for dissipating heat from objects to be cooled comprises cooling zones each with a heat-sink structure as a component of a heat sink of the cooling component, a fin or pin structure comprising fins or pins spaced at equal distances as well as heat-sink flow channels delimited by adjacent fins or pins, through which cooling medium can flow in parallel, which can be supplied to the cooling component via an inlet of the cooling component and which can be discharged from it via an outlet of the cooling component. At least one of the cooling zones comprises, in addition to its heat-sink flow channels, at least one side-flow channel connected in parallel to these heat-sink flow channels for reducing flow resistance or for passing through particles contained in the cooling medium.

### CROSS-REFERENCE TO RELATED APPLICATIONS

This patent application is a continuation of, and as such claims priority to, International Patent Application No. PCT/EP2024/064166, filed on May 23, 2024, which claims priority to and all advantages of German Patent Application No. DE 10 2023 113 544.9, filed on May 24, 2023; each of the foregoing applications are incorporated herein by reference in their entireties.

### BACKGROUND

Cooling components that are flowed through by a cooling medium or can be flowed through are used, for example, for power electronics components, such as power electronics semiconductor modules. It is desirable for cooling components to be particularly efficient. They usually have a metallic heat sink, i.e., a heat sink made of metal or a metal alloy (where applicable, coated) with a flat heat absorption side formed by a cooling surface, which is as close as possible when the cooling component is used to optimize heat transfer—under direct installation or by means of an intermediate layer of thermal interface material, in particular thermal paste—should be placed on a (for example, also planned) heat emission side of the object to be cooled. The heat sink then absorbs the waste heat of the object to be cooled, which, in turn, is then dissipated by the cooling medium. The cooling medium flows inside the cooling component through the heat-sink structures of the cooling zones.

U.S. Pat. No. 11,525,638 B2 discloses a heat exchanger assembly comprising a cold plate having at least one external heat transfer surface designed for thermal contact with one or a plurality of heat-generating substrates. A fluid flow path extends from an inlet port to an outlet opening, with a variety of cooling zones spaced along the fluid flow path, wherein each cooling zone comprises a heat transfer element such as a corrugated fin sheet in contact with the inner surface of the first panel wall. One or more bypass flow channels are provided between upstream and downstream ends of at least one cooling zone to divert some of the heat transfer fluid so that it does not flow through the cooling zone.

### SUMMARY

The present disclosure relates to a cooling component for the dissipation of heat from objects to be cooled with one or a plurality of cooling zones, each with a heat-sink structure as part of a heat sink of the cooling component, in particular, a fin or a pin structure, wherein the heat-sink structure comprises, in particular, fins or pins spaced at equal intervals as well as heat-sink flow channels delimited by adjacent fins or pins, through which cooling medium, which can be supplied to the cooling component via an inlet of the cooling component, and which can be discharged from the cooling component via an outlet of the cooling component after the cooling component flowed through it, can flow through, in particular, parallel.

Typically, in such heat sinks, the individual fins or (fin) pins of the heat-sink structures are very thin and the heat-sink flow channels limited by them are very narrow. However, very narrow heat-sink flow channels generate a high pressure loss. This leads to an unfavourably high flow resistance, particularly in view of the series connection of the individual cooling zones in the cooling component, which has a negative effect on the performance of the cooling component. In addition, the narrow heat-sink flow channels can quickly become clogged with dirt particles or other material particles. Which can be contained in the cooling medium, which, where applicable, has a negative effect on their performance.

A cooling component is accordingly characterized in that one, a plurality of or each cooling zone, in addition to its heat-sink flow channels delimited by adjacent fins or pins, comprises at least one side-flow channel connected parallel to these heat-sink flow channels, in particular, to reduce the flow resistance of the respective cooling zone compared to such a cooling zone without such a side-flow channel and/or to reduce the flow resistance of the respective cooling zone and/or for passing through any particles contained in the cooling medium that do not fit through the heat-sink flow channel, wherein the cooling component comprises one or a plurality of guiding elements that guide the particles, where applicable, located in the cooling medium, where applicable, that could block the heat-sink flow channels, in the direction of the side-flow channel so that they flow through the side-flow channel.

It has been shown that by (at least) such a parallel side-flow channel, the flow resistance of the respective cooling zone can be significantly reduced compared to such a cooling zone without such a side-flow channel. In practice, it is favourable to provide a plurality of such side-flow channels per cooling zone in order to optimize the effect of reducing flow resistance.

Depending on the design of the dimensions of the side-flow channel, it is also possible to prevent the flow channels from becoming clogged with the above-mentioned particles, either alternatively or additionally, since they then flow along the side-flow channel and can then be led out of the cooling component.

As with the heat-sink flow channels, the cooling medium can also be supplied via the inlet of the cooling component in accordance with the respective side-flow channel, and after flowing through it, the cooling medium can then be discharged from the cooling component via the outlet of the cooling component.

Preferably, a plurality of the cooling zones with such a side-flow channel can be connected in series so that the cooling medium supplied via the inlet would flow through them one after the other. In addition to the heat-sink flow channels of their respective heat-sink structure, the cooling zones connected in series can then comprise at least one side-flow channel connected in parallel to the heat-sink flow channels. In particular, such a side-flow channel can be connected in parallel to a group of such cooling zones connected in series.

Preferably, the or any side-flow channel can comprise an open longitudinal side along its longitudinal extension running in the main flow direction in the side-flow channel at least across a large part of its length, to which it connects to open longitudinal sides of the heat-sink flow channels so that cooling medium can flow across these open longitudinal sides between the heat-sink flow channels and the side-flow channel.

In addition or as an alternative, it can be provided that the side-flow channel is closed along its longitudinal extension running in the main flow direction in the side-flow channel for at least a large part of its length so that cooling medium cannot flow there between the heat-sink flow channels and the side-flow channel.

The side-flow channel of one or any of the cooling zones or of the cooling zones connected in series can also extend along the entire length of the heat-sink flow channels of the heat-sink structure of the respective cooling zone, in particular, parallel to the heat-sink flow channels.

The side-flow channel of one or any cooling zone or of the cooling zones connected in series can be adjacent on one side, in particular, on an open longitudinal side of the side-flow channel, to free ends of the fins or pins of the corresponding heat-sink structure of that cooling zone, and to open sides (in particular, longitudinal sides) of the heat-sink flow channels of that heat-sink structure, preferably with a fluid-conveying connection of the side-flow channel to the heat-sink flow channels. In this example, the fins or pins of the heat-sink structure of the respective cooling zone would therefore comprise free ends, in the area in which the heat-sink flow channels arranged between them or formed by them would also be correspondingly open (for example, at the (open) top side of the heat-sink flow channels opposite the bottom side of the heat-sink flow channels) and merge directly into the side-flow channel there or at this connect.

Furthermore, it can be provided that the main flow direction of the side-flow channel of one or each of the cooling zones connected in series runs parallel to the respective main flow direction in the heat-sink flow channels of the heat-sink structure. In addition, or as an alternative, it can be provided that the side-flow channel runs at least predominantly parallel to the heat-sink flow channels of one or every cooling zone or of the cooling zones connected in series.

Furthermore, the side-flow channel of one or each cooling zone or each of the cooling zones connected in series can cover a plurality of heat-sink flow channels of the heat-sink structure of the respective cooling zone transverse to the main flow direction in the side-flow channel or perpendicular to the longitudinal extension of the same, in particular, all heat-sink flow channels of this heat-sink structure or at least 80% of the heat-sink flow channels thereof.

Furthermore, the respective side-flow channel of one or any of the cooling zones connected in series can extend along the entire length of the heat-sink flow channels of the heat-sink structure of the respective cooling zone, in particular, parallel to the heat-sink flow channels.

The main flow direction of the respective side-flow channel and/or its longitudinal axis of one or each of the cooling zones connected in series can preferably run parallel to the respective main flow direction in the heat-sink flow channels of the heat-sink structure and/or parallel to the longitudinal axis of the heat-sink flow channels.

With regard to the flow cross-section in the side-flow channel of one or each of the cooling zones connected in series, this can be greater than the flow cross-section of one or each of the heat-sink flow channels of the heat-sink structure of the respective cooling zone.

Preferably, the shape and/or size of the flow cross-section of the side-flow channel of one or a plurality of cooling zones or of the cooling zones connected in series can be chosen in such a way that particles located in the cooling medium, where applicable, which do not fit through the heat-sink flow channels of the relevant cooling zone can flow through the side-flow channel without blocking it, in particular, particles whose size is ≥0.3 mm², in particular, ≥0.3 mm² and ≤1.2 mm².

In addition or as an alternative, it can be provided that the size of the flow cross-section of the side-flow channel of one or each cooling zone, or each of the cooling zones connected in series is significantly larger than the flow cross-section of one or each of the heat-sink flow channels of the respective cooling zone, in particular, at least twice, preferably at least five times as large.

It is particularly preferable that two or two cooling zones immediately following each other in a row can be spatially separated from each other by the cooling zones connected in series, in particular, by forming a mixing zone arranged between these spatially spaced cooling zones for the cooling zone arranged upstream in the row. In this mixing zone, the cooling medium flowing through the side-flow channel of the cooling zone arranged upstream can then mix with the cooling medium flowing through the heat-sink flow channels of its heat-sink structure.

Such mixing increases the efficiency of the cooling component. This is because, in particular, if the side-flow channel is further away from the heat sink of the cooling component than the heat-sink flow channels of the respective heat-sink structure, the cooling medium in the heat-sink flow channels is heated significantly more than the cooling medium in the side flow by the waste heat of the object to be cooled. The aforementioned (vertical) mixing then ensures that the cooling medium of the side flow can also be used effectively for cooling.

In the context of the concrete implementation, the mixing zone can comprise a fluid-conveying mixing channel connected both to the side-flow channel of the upstream cooling zone and to the heat-sink flow channels of the upstream cooling zone.

A plurality of, preferably at least two cooling zones of the cooling component, in particular, two cooling zones, each connected in series with a different cooling zone, can also be connected in parallel so that the cooling medium supplied via the inlet of the cooling component would flow through them in parallel.

The cooling component can then comprise a mixing zone downstream of one of the cooling zones connected in parallel for those cooling zones connected in parallel, in which the cooling medium flowing through the two cooling zones or already flowing (exiting from them) can mix (horizontally), in particular, the cooling medium flowing through the heat-sink flow channels of their heat-sink structures and/or the cooling medium flowing or flowing through their respective side-flow channels. One of the advantages of this is that the cooling medium of one of the cooling zones connected in parallel, which cannot have heated up as much, where applicable, because this cooling zone is located at the edge of the cooling component, can mix with more heated cooling medium that has escaped from one, a plurality of or all of the other cooling zones connected in parallel.

In a further example, one of the parallel-connected cooling zones can at the same time form or be the downstream cooling zone of the two cooling zones immediately following each other in a row.

The mixing zone for the cooling zones connected in parallel can comprise a fluid channel located downstream of these cooling zones, in particular, running transversely to the heat-sink flow channels of these cooling zones, connecting the two cooling zones in a fluid-guiding manner. This fluid channel can then be used the cooling medium exchange between the cooling zones connected in parallel, or mixing can also take place in the fluid channel.

As far as the above-mentioned mixing is concerned, this is preferably carried out at an angle, in particular, transversely to the main flow direction of the side-flow channel and/or at an angle or transverse to the longitudinal extension direction of the same.

It can be provided that at least one element is assigned to the fluid channel for mixing the cooling medium that has escaped from the cooling zones connected in parallel. In particular, the element can be a guiding element, in particular, a guiding element which is arranged in the fluid channel and is directed with the cooling medium which has escaped from one of the cooling zones connected in parallel after it has flowed through it, in the direction of the cooling medium which has escaped from that other cooling zone after flowing through another of the cooling zones connected in parallel.

The cooling component comprises one or a plurality of guiding elements which guide any particles, located in the cooling medium, where applicable, which could block the heat-sink flow channels due to their size, in the direction of the side-flow channel so that they flow through the side-flow channel.

This effectively prevents such dirt or material particles adversely clog the heat-sink structure with its narrow heat-sink flow channels. Instead, they would be diverted into the side-flow channel, which can then favourably comprise a larger cross-section and/or a greater width than the individual heat-sink flow channels for this purpose.

The heat-sink structure can comprise an inclined or oblique flank at its upstream end compared to the main flow direction and/or the longitudinal extension direction of the heat-sink flow channels in the flow channels. In particular, an inclined flank that is shaped in such a way that any dirt particles or other material particles, where applicable, in the cooling medium are deflected in the direction of the side-flow channel when the cooling medium hits the inclined flank so that they flow through the side-flow channel.

The inclined flank can then be formed, for example, if it has fins, by correspondingly inclined narrow sides of the fins of the heat-sink structure, and/or, if it comprises pins, by groups of pins of the heat-sink structure, wherein the height of the individual pins then differs accordingly from group to group as this flank is formed.

As regards the heat sink of the cooling component, it can comprise or be formed by a component made of metal (where applicable coated) or of a metal alloy (where applicable, coated) which has on the side the heat-sink structure of one, a plurality of or any cooling zone which is turned away from a particularly flat cooling surface of the cooling component to which an object to be cooled can be brought from it to the installation in order to absorb heat.

Preferably, the cooling surface of the cooling component is then an (external) side of the heat sink.

Ultimately, the side-flow channel and/or the heat-sink flow channels may be covered on the side facing away from the cooling surface by a wall of the cooling component which delimits the side-flow channel and/or the heat-sink flow channels to that side, in particular, by a bottom part of the cooling component, being adjacent to the external environment, forming that wall.

### BRIEF DESCRIPTION OF THE DRAWINGS

FIG. 1 shows a cooling component in oblique view from above.

FIG. 2 shows the cooling component from FIG. 1 in oblique view from below.

FIG. 3 shows the cooling component from FIG. 1 in an exploded illustration.

FIG. 4 shows the cooling component from FIG. 1 in a horizontal section.

FIG. 5 shows the cooling component from FIG. 1 in a first longitudinal section along the intersection line V-V in FIG. 4.

FIG. 6 shows the cooling component from FIG. 1 in a second longitudinal section along the intersection line VI-VI in FIG. 4.

FIG. 7 shows the cooling component from FIG. 1 in a first cross-section along the intersection line VII-VI in FIG. 4.

FIG. 8 shows the cooling component from FIG. 1 in a second cross-section along of the section line VIII-VIII in FIG. 4.

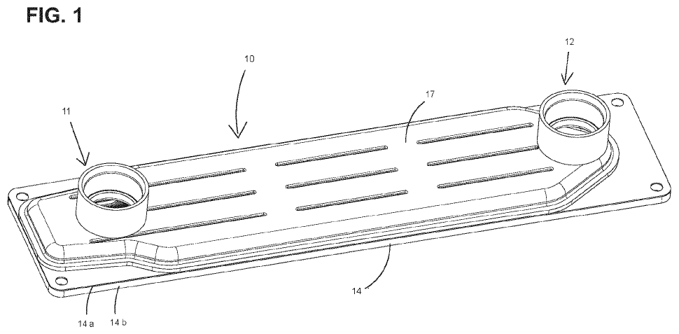

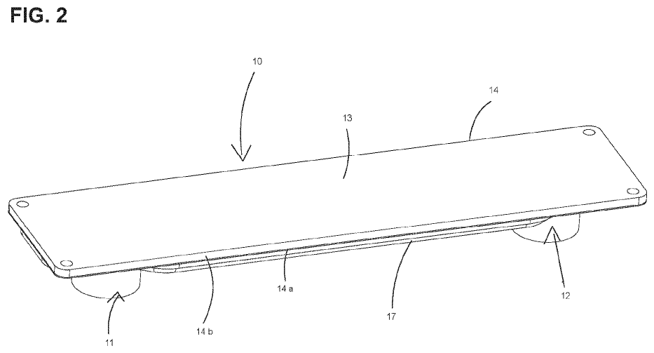

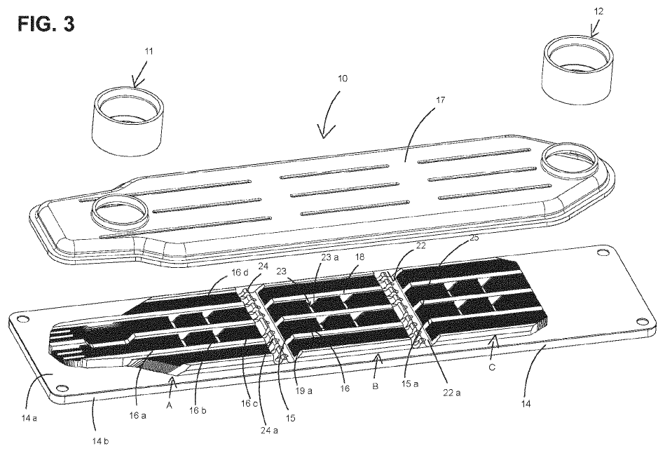

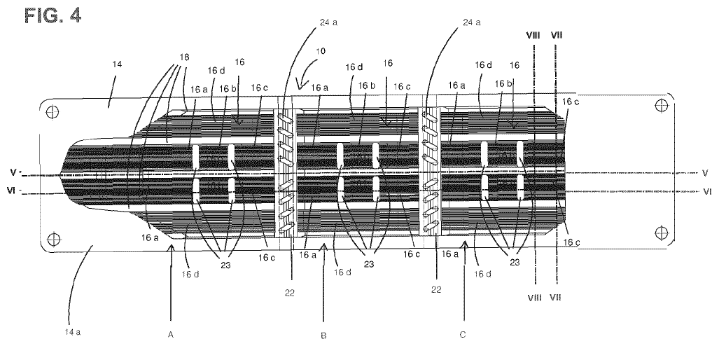

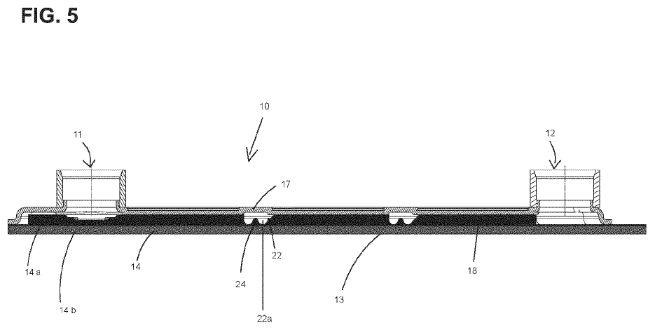

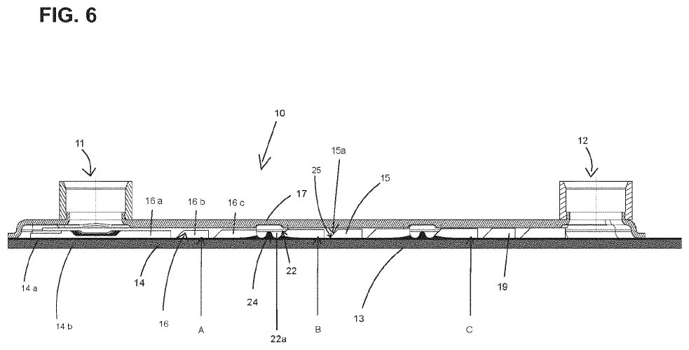

### DETAILED DESCRIPTION

The cooling component 10 shown in the figures, on the bottom side of which objects to be cooled that are not shown can be arranged in order to dissipate heat from them to the cooling component 10, is in the present housing part of a higher-level cooling device that is otherwise not shown in more detail.

The cooling device and its cooling component 10 can be used, for example, to cool power electronics units, such as power electronics semiconductor modules. Such power electronic components are used, among other things, in connection with batteries or rechargeable batteries of electric vehicles. However, it is to be understood that the type of components to be cooled does not matter.

The higher-level cooling device can, among other things, comprise or be filled with a cooling medium that is conveyed by means of a pump through the cooling component 10 so that it flows through the cooling component 10 and absorbs and dissipates heat from the object to be cooled on its way through the cooling component 10. For this purpose, the pump can be connected to an inlet 11 and an outlet 12 of the cooling component 10 by means of medium-conveying pipes, such as hoses for example.

As a rule, the cooling medium will be a cooling medium. However, it is to be understood that it is also within the scope of the disclosure to use a gaseous medium as a cooling medium.

The cooling component 10 comprises a metallic heat sink 14.

In the present case, the heat sink 14 is constructed in two parts, namely comprising an upper heat-sink part 14a and a lower heat-sink part 14b that is plate shaped, which is thermally conductively connected to the bottom side of the upper heat-sink part 14a (directly or by means of a heat paste attached to it).

The upper heat-sink part 14a is made of a first (metallic) material with a slightly lower thermal conductivity, such as aluminium, which has certain manufacturing advantages, and the lower heat-sink part 14b, which comes into direct contact with the objects to be cooled, is made of a second (metallic) material that is more thermally conductive than aluminium, such as copper.

Heat sink 14, in this case its upper heat-sink part 14a, comprises-in the present case material-tight or material-uniformly connected to it-a large number of heat-sink structures or fin structures with individual thin-walled (material) fins 19 as well as narrow heat-sink flow channels 20 delimited by these, through which the cooling medium flows during operation of the cooling device, coming from the direction of inlet 11 in the direction of outlet 12.

In other words, the heat sink 14 or the upper heat-sink part 14a comprises the aforementioned heat-sink structures 15, for example, they are milled into them or moulded in some other way.

In the transverse direction of cooling component 10, the individual heat-sink structures 15 are separated from each other by partition walls 18.

Towards the top, the heat sink 14 is covered and sealed by a housing part 17, for example made of metal or plastic.

In the present case, the bottom side of the heat sink 14 or the lower heat-sink part 14b also forms a heat absorption side 13 of the cooling component 10, to which the components to be cooled are attached during cooling mode.

Each heat-sink structure 15 is part of a single, assigned cooling zone 16, through which the cooling medium flows. As can be seen, heat sink 14 in the present case comprises three similar segments A, B and C, each with a plurality of cooling zones 16, each of which is arranged one after the other in relation to the medium flow resulting from inlet 11 to outlet 12.

The heat sink 14 comprises four rows of cooling zones 16 connected in series in the transverse direction of the cooling component 10, namely two middle rows and two outer rows. The middle rows comprise three cooling zones 16a, 16b or 16c in each segment A, B, C and the outer rows each comprise one cooling zone 16d in each segment A, B, C.

In each segment A-C, but also across segments, different cooling zones 16 are connected in series so that the medium flow flows through them one after the other.

Within the respective segment A, B, C, the individual cooling zones 16a, 16b, 16c are each connected in series one after the other.

In addition, the cooling zones 16c and 16a are connected in series across the segments and the individual cooling zones 16d.

The individual fins 19 of the heat-sink structures 15 of the cooling zones 16 are typically very thin and the heat-sink flow channels 20 they delimited are very narrow. However, very narrow heat-sink flow channels 20 generate a high pressure loss. This leads to an unfavourably high flow resistance, particularly in view of the series connection of the individual cooling zones 16 in the cooling component.

The cooling component 10, namely in the present case each cooling zone 16 of the same, therefore comprises a side-flow channel 21 extending parallel to the heat-sink flow channels 20, which is also connected in parallel to the respective heat-sink flow channels 20 of the respective cooling zone 16 and whose purpose is, inter alia, to reduce the flow resistance.

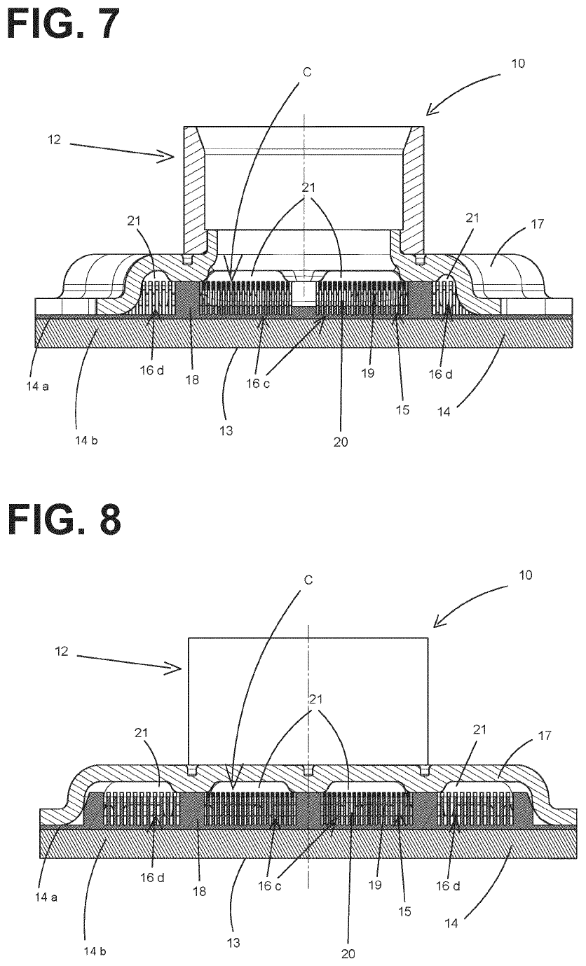

As can be seen in FIGS. 7 and 8 in particular, these side-flow channels 21 also run parallel to the main flow direction within the heat-sink flow channels 20, in the present case, above the respective heat-sink structure 15.

The side-flow channels 21 are adjacent on an open (lower) side of the same to free ends of the fins 19 of the corresponding heat-sink structure 15 and to the corresponding open bottom sides of the heat-sink flow channels 20 opposite sides of the heat-sink flow channels 20 of this heat-sink structure 15, and, in this case, under a fluid-conveying connection with the heat-sink flow channels 20.

Each side-flow channel 21 of cooling zones 16 covers a plurality of heat-sink flow channels 20 of the heat-sink structure 15 of the respective cooling zone 16 (or 16a-d) at right angles to the main flow direction in the side-flow channel 21, in this case at least 80 % of the respective total number of heat-sink flow channels 20 of the respective cooling zone 16 of the same.

To the top and to the side, the side-flow channels 21 and ultimately also the heat-sink flow channels 20 connected to them in the present case (via the open longitudinal sides) are delimited by corresponding walls of the housing part 17 adjacent to the external environment.

It has been shown that the flow resistance of the respective cooling zone 16 can be significantly reduced by the side-flow channels 21 connected parallel to the heat-sink flow channels 20 of the respective cooling zone 16 compared to such a cooling zone 16 without such a side-flow channel 21. This is particularly the case if, as in the present case, the cross-section of the respective side-flow channel 21 is significantly larger than the cross-section of each individual heat-sink flow channel 20 of the respective heat-sink structure 15 of the respective cooling zone 16 or even greater than the sum of the cross-sections of the individual heat-sink flow channels 20 of the same.

As already indicated above, two of a series of immediately consecutive cooling zones 16 are spatially separated from each other.

Within a segment A, B, C, for example, the cooling zones 16a and 16b from each other and the cooling zones 16b and 16c from each other.

On the other hand, for example, the cooling zones 16d of the preceding segments A or B relative to the cooling zones 16d of the subsequent segments B or C. Furthermore, the cooling zone 16c of the upstream or preceding segment A or B relative to the cooling zone 16a of the following or downstream segment B or C.

Between or in the open spaces of the cooling zones 16a and 16b or 16b and 16c within a segment A, B, C, which are spatially separated from each other in this way, mixing zones 23 are formed.

Mixing zones 22 are formed between or in the open spaces of the spatially spaced cooling zones 16c and 16a or 16d and 16d of consecutive segments A and B and B and C, respectively.

The mixing zones 22 comprise mixing channels 22a, which connect the side-flow channel 21 with the heat-sink flow channels 20 of the respective cooling zone 16 in a medium- or fluid-conveying manner.

In the mixing zones 23 or via their mixing channels 23a, the cooling medium flowing through the side-flow channel 21 of the respective cooling zones 16a or 16b or 16c then mixes favourably, particularly in the vertical direction (transverse to the main flow direction in the side-flow channel 21) or from top to bottom (and vice versa) with the cooling medium of the respective cooling zone 16a or 16b or 16c flowing through the heat-sink flow channels 20 of their heat-sink structure 15. The vertical mixing of the cooling medium flowing through the side-flow channel 21 with the cooling medium in the respective cooling zones 16a or 16b or 16c is carried out by a reduction of the flow velocity in the mixing channels 23a due to the absence of heat-sink structures 15 in connection with a higher flow velocity in the side-flow channel 21.

This causes the cooling medium to rotate so that mixing takes place from bottom to top and vice versa. In addition, the cooling medium from the side-flow channel 21 meets the heat-sink structures 15, in particular, their flanks 15a, which are preferably bevelled, as described below so that the cooling medium is deflected, which leads to further mixing, particularly in the vertical direction, but also partially in the horizontal direction.

Such mixing increases the efficiency of cooling component 10. This is because the side-flow channel 21 is further spaced from the heat absorption side 13 of the heat sink 14 or the cooling component 10 than the heat-sink flow channels 20 of the respective heat-sink structure 15 so that the cooling medium in the heat-sink flow channels 20 is heated significantly more by the waste heat of the object to be cooled than the cooling medium in the side-flow channel 21. The aforementioned mixing then ensures that the cooling medium in the side-flow channel 21 also participates effectively in the cooling.

The mixing zones 22 arranged between the respective segments A and B and B and C each comprise a mixing channel 22a, through which a (in this case horizontal) mixing of the cooling zones 16c and 16d of the respective segment A and B leaked cooling medium.

Among other things, this has the advantage that, for example, a cooling medium that has flowed through the two peripheral cooling zones 16d and cannot have been heated as much by the object to be cooled, where applicable, can mix with the more heated cooling medium of the adjacent cooling zone(s) 16c. This also clearly increases the efficiency of cooling component 10.

In the mixing channel 22a, individual guiding elements 24 of the heat sink 14 are arranged with guide channels 24a running at an angle to the main flow direction in the heat-sink flow channels 20 and in the side-flow channels 21a, which promote the (horizontal) mixing by directing the cooling medium that has escaped from the cooling zones 16c and 16d respectively in this case (horizontally) towards the middle-in the direction.

In the present case, these are components of the heat sink part 14 a that are uniform in terms of material or are formed/shaped from it.

It is to be understood, however, that the guiding elements 24 can also be formed by separate components and/or can be formed differently than described here. For example, they can also be designed in such a way that they primarily cause a redirection or redirection of the (warm) cooling medium from the cooling zones 16c, which are located further inside, in the direction of the cooling zones 16d on the edge side.

Furthermore, it is to be understood that such (horizontal) mixing does not take place exclusively in mixing zone 22 or mixing channel 22a. As is the case in mixing zones 23, there is also vertical mixing between the cooling medium exiting the side-flow channels 21 and the cooling medium leaving the heat-sink flow channels 20.

The side-flow channels 21 have another purpose-in addition to reducing flow resistance. This is because it prevents particles, where applicable, contained in the cooling fluid from clogging the very narrow heat-sink flow channels 20 due to their size. This is because these can then flow along the significantly larger side-flow channel 21 and thus be guided out of the cooling component 10 in this way.

In order to ensure that the particles are also led to the side-flow channel 21, guiding elements 25 are provided with which they can be directed to the respective side-flow channel 21.

In the present case, the guiding elements 25 are formed by flanks 15a of the heat-sink structures 15 of the individual cooling zones 16, each of which comprises such a flank 15a at their respective upstream ends, which is inclined or oblique with respect to the main flow direction in their heat-sink flow channels 20.

An inclined flank 15a formed in this way then ensures that dirt particles or other material particles in the cooling medium, which would otherwise clog the heat-sink flow channels 20, are deflected in the direction of the side-flow channel 21 when the cooling medium hits the inclined flank 15a and can then flow through it without any problems.

The inclined flank 15a of the heat-sink structure 15 is formed by correspondingly inclined narrow sides 19a of the individual fins 19 of the heat-sink structure 15.

As already indicated, the side-flow channels 21 are sufficiently large so that the particles that do not fit through the heat-sink flow channels 20 (together with the cooling medium) can pass through them. In the present case, the dimensions of the heat-sink flow channels 20 in the spatial direction in which they are arranged next to each other (in FIGS. 8 and 9 respectively in a horizontal spatial direction) are at least ten times smaller than the dimensions of the side-flow channel 21 in the same spatial direction.

It is to be understood that in practice the shape and/or size of the flow cross-section of the respective side-flow channel 21 is chosen in such a way that particles that can be expected to be present in the cooling medium, where applicable, and do not fit through the heat-sink flow channels 20, in particular, (by way of example only) particles whose size is ≥0.3 mm2, in particular, ≥0.3 mm2 and ≤1.2 mm2, can flow through the respective side-flow channel 21 without blocking it. The respective design of the (transverse) dimensions of the respective side-flow channel 21 therefore also depends on the size of the particles that will presumably be contained in the cooling medium as dirt particles, etc.

Accordingly, the size or area of the flow cross-section of the side-flow channel 21 shall be sufficiently larger than the flow cross-section of one or each flow channel 20 of the heat-sink flow channels 20 in accordance with the particle size of the largest particles to be expected in the cooling medium, in particular, at least twice as large, preferably at least five times as large.

All the features described in the embodiments explained above on the basis of the drawings are to be understood only as examples and do not constitute a limitation of the subject-matter according to the invention.

### LIST OF REFERENCE NUMBERS

A-C segments
10 cooling component
11 inlet
12 outlet
13 heat absorption side
14 heat sink
14a upper heat-sink part
14b lower heat-sink part
15 heat-sink structures
15a flank of the heat-sink structure
16a-d cooling zones
17 housing part
18 partition walls
19 fins
19a side of the fins
20 heat-sink flow channels
21 side-flow channels
22 horizontal mixing zone
22a mixing channels
23 vertical mixing zone
23a mixing channels
24 guiding elements
24a guide channels
25 guiding elements for particles

1. A cooling component for the dissipation of heat from objects to be cooled, comprising:
one or a plurality of cooling zones each with a component of a heat-sink structure forming the cooling component, which comprises fins or pins that are spaced apart as well as heat-sink flow channels, through which cooling medium is able to flow, delimited by fins or pins that are adjacent;
an inlet of the cooling component, via which the cooling medium is supplied to the cooling component;
an outlet of the cooling component, via which the cooling medium can be discharged from the cooling component after the cooling medium flowed through the cooling component;
wherein one of the cooling zones, a plurality of the cooling zones, or each cooling zone comprises, in addition to the heat-sink flow channels delimited by the adjacent fins or pins, at least one side-flow channel connected in parallel to the heat-sink flow channels to pass through any particles contained in the cooling medium that do not fit through the heat-sink flow channels; and
the cooling component comprises at least one guiding element, which guides the particles located in the cooling medium, that would block the heat-sink flow channels due to their size, toward the side-flow channel so that the particles flow through the side-flow channel.

2. The cooling component according to claim 1, wherein at least two of the cooling zones are connected in series so that cooling medium supplied via the inlet would flow through successively supplied via the inlet.

3. The cooling component according to claim 2, wherein the cooling zones connected in series each comprise at least one side-flow channel connected in parallel to the heat-sink flow channels in addition to the heat-sink flow channels of the respective heat-sink structures of the cooling zones connected in series.

4. The cooling component according to claim 1, wherein the side-flow channel of at least one of the cooling zones is adjacent on an open longitudinal side, to free ends of the fins or pins of the corresponding heat-sink structure of the respective cooling zone and to open longitudinal sides of the heat-sink flow channels of the respective heat-sink structure under fluid-conveying connection with the heat-sink flow channels.

5. The cooling component according to claim 1, wherein the side-flow channel along a longitudinal extension of the side-flow channel running in a main flow direction in the side-flow channel comprises an open longitudinal side at least across a large part of a length of the side-flow channel, at which the open longitudinal side of the side-flow channel connects to an open longitudinal side of the heat-sink flow channels so that the cooling medium is transferred over the open longitudinal sides between the heat-sink flow channels and the side-flow channel.

6. The cooling component according to claim 1, wherein the side-flow channel of at least one of the cooling zones extends along an entire length of the heat-sink flow channels of the heat-sink structure of the respective cooling zone parallel to the heat-sink flow channels.

7. The cooling component according to claim 1, wherein at least one of (1) a main flow direction of the side-flow channel of at least one of the cooling zones runs parallel to a respective main flow direction in the heat-sink flow channels of the heat-sink structure, or (2) the side-flow channel runs at least predominantly parallel to the heat-sink flow channels of at least one of the cooling zones.

8. The cooling component according to claim 1, wherein at least one of a shape or size of the flow cross-section of the side-flow channel of at least one of the cooling zones is chosen in such a way that particles in the cooling medium are able to flow through the side-flow channel without blocking the side-flow channel, which particles do not fit through the heat-sink flow channels of the respective cooling zone.

9. The cooling component according to claim 1, wherein the side-flow channel of at least one of the cooling zones transversely to a main flow direction in the side-flow channel covers a plurality of heat-sink flow channels of the heat-sink structures of the respective cooling zones.

10. The cooling component according to claim 1, wherein one of the cooling zones is spatially separated from the cooling zones that are connected in series, forming a mixing zone arranged between the spatially spaced cooling zones for the cooling zones arranged upstream in the series, in which the cooling medium of the cooling zone arranged upstream flowing through the side-flow channel mixes together with the cooling medium flowing through the heat-sink flow channels of its heat-sink structure in directions at angles transversely to a main flow direction of the side-flow channel.

11. The cooling component according to claim 10, wherein the mixing zone comprises a fluid-conveying mixing channel connected both to the side-flow channel of the upstream cooling zone as well as to the heat-sink flow channels of the upstream cooling zone.

12. The cooling component according to claim 1, wherein at least two of the cooling zones of the cooling component, each connected in series with a different one of the cooling zones, are connected in parallel so that the cooling medium flows through them in parallel which is supplied via the inlet of the cooling component, and that the cooling component downstream of these parallel connected cooling zones comprises a mixing zone for these cooling zones connected in parallel, in which the cooling medium flowing through these cooling zones mixes.

13. The cooling component according to claim 12, wherein one of the parallel-connected cooling zones forms a downstream cooling zone of the two cooling zones immediately following each other in a series.

14. The cooling component according to claim 12, wherein the mixing zone for the parallel connected cooling zones comprises a fluid channel arranged downstream of the parallel connected cooling zones running transversely to the heat-sink flow channels of these cooling zones, connecting the cooling zones in a fluid-conveying manner, in which the at least one guiding element is placed, wherein the cooling medium which has escaped from a first of the parallel connected cooling zones after flowing through the first of the parallel connected cooling zones from a cooling zone arranged further outwards is directed by the at least one guiding element toward the cooling medium which has escaped from a second cooling zone after flowing through a different one of the cooling zones from one of the cooling zones located further inside.

15. The cooling component according to claim 1, wherein the heat-sink structure of at least one of the cooling zones comprises at an upstream end of the cooling zone a flank inclined with respect to a main flow direction in the heat-sink flow channels of the heat-sink structure.

16. The cooling component according to claim 15, wherein the flank is formed by one of (1) correspondingly inclined narrow sides of the fins of the heat-sink structure or (2) the flank is formed by groups of pins of the heat-sink structure, wherein heights of the individual pins forming the flank differ from group to group.

17. The cooling component according to claim 1, wherein the heat sink includes a component made of metal, which has on the side the heat-sink structure of at least one of the cooling zones, which is turned away from a particularly flat cooling surface of the cooling component, to which an object to be cooled that is brought absorbs heat from the object.

18. The cooling component according to claim 1, wherein a cooling surface of the cooling component is an external side of the heat sink.

19. The cooling component according to claim 1, wherein at least one of the side-flow channel or the heat-sink flow channels on the side facing away from a cooling surface are covered by a wall of the cooling component which bounds the at least one of the side-flow channel or the heat-sink flow channels to that side by a bottom part of the cooling component forming this wall and adjacent to an external environment.
